(19) United States
(12) Patent Application Publication
(10) Pub. No.: US 2019/0126428 A1
(43) Pub. Date: May 2, 2019

(54) HEAT EXCHANGER FOR REGULATING TEMPERATURE OF POLISHING SURFACE OF POLISHING PAD, POLISHING APPARATUS HAVING SUCH HEAT EXCHANGER, POLISHING METHOD FOR SUBSTRATE USING SUCH HEAT EXCHANGER, AND COMPUTER-READABLE STORAGE MEDIUM STORING A PROGRAM FOR REGULATING TEMPERATURE OF POLISHING SURFACE OF POLISHING PAD

(71) Applicant: EBARA CORPORATION, Tokyo (JP)

(72) Inventors: Toru MARUYAMA, Tokyo (JP); Yasuyuki MOTOSHIMA, Tokyo (JP); Hisanori MATSUO, Tokyo (JP); Masashi KABASAWA, Tokyo (JP)

(21) Appl. No.: 16/173,937

(22) Filed: Oct. 29, 2018

(30) Foreign Application Priority Data
Oct. 31, 2017 (JP) 2017-210186
Jun. 20, 2018 (JP) 2018-116659

(51) Int. Cl. B24B 37/015; B24B 37/04; H01L 21/306; F28F 19/04; F28G 1/16

(52) U.S. Cl. CPC B24B 37/015; B24B 37/042; F28F 2245/04; F28F 19/04; F28G 1/166; H01L 21/30625

(57) ABSTRACT

A heat exchanger capable of preventing sticking of slurry is disclosed. The heat exchanger includes: a flow passage structure having a heating flow passage and a cooling flow passage formed therein; and a water-repellent material covering a side surface of the flow passage structure. A side surface of the heat exchanger is constituted by the water-repellent material.

### CROSS REFERENCE TO RELATED APPLICATIONS

This document claims priorities to Japanese Patent Application Number 2017-210186 filed Oct. 31, 2017 and Japanese Patent Application Number 2018-116659 filed Jun. 20, 2018, the entire contents of which are hereby incorporated by reference.

### BACKGROUND

A CMP (chemical mechanical polishing) apparatus is used in a process of polishing a surface of a wafer in the manufacturing of a semiconductor device. The CMP apparatus is configured to hold and rotate the wafer with a polishing head, and press the wafer against a polishing pad on a rotating polishing table to polish the surface of the wafer. During polishing, a slurry is supplied onto the polishing pad, so that the surface of the wafer is planarized by the chemical action of the slurry and the mechanical action of abrasive grains contained in the slurry.

A polishing rate of the wafer depends not only on a polishing load on the wafer pressed against the polishing pad, but also on a surface temperature of the polishing pad. This is because the chemical action of the slurry on the wafer depends on the temperature. Therefore, in the manufacturing of a semiconductor device, it is important to maintain an optimum surface temperature of the polishing pad during polishing of the wafer in order to increase the polishing rate of the wafer, and to keep the increased polishing rate constant.

From this viewpoint, a pad-temperature regulating device is conventionally used to regulate a temperature of a polishing surface of a polishing pad. This pad-temperature regulating device includes a heat exchanger disposed above the polishing pad (see, for example, Japanese laid-open patent publication No. 2015-044245). During polishing of the wafer, with the slurry present between the polishing pad and the heat exchanger, the heat exchanger performs heat exchange between the polishing pad and a fluid flowing in the heat exchanger, so as to regulate or adjust the temperature of the polishing surface.

Generally, in order to increase the polishing rate (also referred to as removal rate) of the wafer, the polishing surface of the polishing pad is adjusted to a certain high temperature (e.g., about 60° C.) during the polishing of the wafer. In order to maintain such a high temperature, a high-temperature fluid flows in the heat exchanger of the pad-temperature regulating device, and as a result, the heat exchanger itself has a high temperature. During polishing of the wafer, the slurry on the polishing pad contacts the heat exchanger, and a part of the slurry adheres to the heat exchanger. Thus, after polishing the wafer, pure water is sprayed onto the heat exchanger, thereby removing the slurry from the heat exchanger.

However, since the heat exchanger has a considerably high temperature, the slurry attached to the heat exchanger dries during polishing of the wafer and sticks to the side surface of the heat exchanger. The dried slurry may fall onto the polishing pad from the heat exchanger during polishing of the next wafer. A lump of the dried slurry may scratch the surface of the wafer, and may cause a wafer defect. As described above, the heat exchanger is cleaned with pure water after the wafer is polished, but it is difficult to remove the slurry, which has been fixed once, with pure water. In addition, the slurry may dry during the polishing of the wafer and may fall onto the polishing pad.

### SUMMARY OF THE INVENTION

Therefore, according to an embodiment, there is provided a heat exchanger capable of preventing sticking of slurry. According to another embodiment, there is provided a polishing apparatus including such a heat exchanger. According to still another embodiment, there is provided a polishing method of polishing a substrate using such a heat exchanger. According to still another embodiment, there is provided a computer-readable storage medium storing a program for regulating a temperature of a polishing surface of a polishing pad.

Embodiments, which will be described below, relate to an apparatus and a method for regulating a temperature of a polishing surface of a polishing pad used for polishing a substrate, such as a wafer.

In an embodiment, there is provided a heat exchanger comprising: a flow passage structure having a first flow passage and a second flow passage formed therein; and a water-repellent material covering a side surface of the flow passage structure, a side surface of the heat exchanger being constituted by the water-repellent material.

In an embodiment, the water-repellent material comprises a coating layer made of polytetrafluoroethylene.

In an embodiment, the water-repellent material comprises a water-repellent adhesive tape.

In an embodiment, the water-repellent material comprises a silicone rubber.

In an embodiment, the water-repellent material comprises a silicone rubber and a water-repellent coating layer, the water-repellent coating layer covering an outer surface of the silicone rubber.

In an embodiment, there is provided a heat exchanger comprising: a flow passage structure having a first flow passage, a second flow passage, and a pure-water flow passage formed therein, the pure-water flow passage surrounding the first flow passage and the second flow passage; and a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

In an embodiment, the heat exchanger further comprises a heat insulating layer located between the first flow passage and the pure-water flow passage.

In an embodiment, the heat insulating layer comprises an air layer.

In an embodiment, the porous material is made of ceramic.

In an embodiment, there is provided a polishing apparatus comprising: a polishing table for supporting a polishing pad; a polishing head configured to press a substrate against a polishing surface of the polishing pad; a liquid supply nozzle configured to supply slurry or pure water selectively onto the polishing surface of the polishing pad; and a heat exchanger configured to regulate a temperature of the polishing surface by performing heat exchange with the polishing pad, the heat exchanger including: a flow passage structure having a first flow passage and a second flow passage formed therein; and a water-repellent material covering a side surface of the flow passage structure, a side surface of the heat exchanger being constituted by the water-repellent material.

In an embodiment, there is provided a polishing apparatus comprising: a polishing table for supporting a polishing pad; a polishing head configured to press a substrate against a polishing surface of the polishing pad; a liquid supply nozzle configured to supply slurry or pure water selectively onto the polishing surface of the polishing pad; and a heat exchanger configured to regulate a temperature of the polishing surface by performing heat exchange with the polishing pad, the heat exchanger including: a flow passage structure having a first flow passage, a second flow passage, and a pure-water flow passage formed therein, the pure-water flow passage surrounding the first flow passage and the second flow passage; and a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

In an embodiment, there is provided a polishing method comprising: pressing a substrate against a polishing surface of a polishing pad while supplying slurry onto the polishing surface, thereby polishing the substrate; during polishing of the substrate, performing heat exchange between the polishing pad and heating and cooling liquids flowing in a heat exchanger in the presence of the slurry between the polishing surface of the polishing pad and a bottom surface of the heat exchanger; after polishing of the substrate, performing a water polishing process in which pure water is supplied onto the polishing surface of the polishing pad while the substrate is brought into contact with the pure water on the polishing pad; and during the water polishing process, bringing the bottom surface of the heat exchanger into contact with the pure water on the polishing surface of the polishing pad, thereby washing away the slurry from the bottom surface of the heat exchanger, wherein the heat exchanger includes: a flow passage structure having a heating flow passage and a cooling flow passage formed therein; and a water-repellent material covering a side surface of the flow passage structure, a side surface of the heat exchanger being constituted by the water-repellent material.

In an embodiment, the polishing method further comprises spraying pure water onto the side surface of the heat exchanger after the water polishing process.

In an embodiment, there is provided a polishing method comprising: pressing a substrate against a polishing surface of a polishing pad while supplying slurry onto the polishing surface, thereby polishing the substrate; during polishing of the substrate, performing heat exchange between the polishing pad and heating and cooling liquids flowing in a heat exchanger in the presence of the slurry between the polishing surface of the polishing pad and a bottom surface of the heat exchanger; after polishing of the substrate, performing a water polishing process in which pure water is supplied onto the polishing surface of the polishing pad while the substrate is brought into contact with the pure water on the polishing pad; and during the water polishing process, bringing the bottom surface of the heat exchanger into contact with the pure water on the polishing surface of the polishing pad, thereby washing away the slurry from the bottom surface of the heat exchanger, wherein the heat exchanger includes: a flow passage structure having a heating flow passage, a cooling flow passage, and a pure-water flow passage formed therein, the pure-water flow passage surrounding the heating flow passage and the cooling flow passage; and a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

In an embodiment, the polishing method further comprises spraying pure water onto the side surface of the heat exchanger after the water polishing process.

In an embodiment, there is provided a non-transitory computer-readable storage medium storing a program for causing a computer to perform the steps of: instructing a table motor to rotate a polishing table; instructing a polishing head to press a substrate against a polishing surface of a polishing pad on the polishing table to polish the substrate, while instructing a liquid supply nozzle to supply slurry onto the polishing surface; during polishing of the substrate, instructing an elevating mechanism to move a heat exchanger toward the polishing surface to perform heat exchange between the polishing pad and heating and cooling liquids flowing in the heat exchanger in the presence of the slurry between the polishing surface of the polishing pad and a bottom surface of the heat exchanger; and after polishing of the substrate, instructing the liquid supply nozzle to supply pure water onto the polishing surface of the polishing pad to bring the substrate into contact with the pure water on the polishing surface and bring the bottom surface of the heat exchanger into contact with the pure water on the polishing surface to wash away the slurry from the bottom surface of the heat exchanger with the pure water.

According to the above-described embodiments, the side surface of the heat exchanger is made of a water-repellent material. During polishing of the substrate, the slurry that has adhered to the water-repellent material gathers and a volume of the slurry increases. As a result, the slurry is unlikely to dry, and the slurry is prevented from firmly sticking to the side surface of the heat exchanger during polishing of the substrate.

According to the above-described embodiments, the side surface of the heat exchanger is made of a porous material. Pure water, flowing in the pure-water flow passage, exudes through the porous material onto the outer surface of the porous material, i.e., exudes from the side surface of the heat exchanger. As a result, the side surface of the heat exchanger is kept wet. The slurry adhering to the side surface of the heat exchanger does not dry, and firm sticking of the slurry on the porous material is prevented.

According to the above-described embodiments, during the water polishing process, the slurry on the bottom surface of the heat exchanger is washed away with the pure water existing on the polishing pad. Therefore, the water polishing process can remove the slurry from the bottom surface of the heat exchanger.

### BRIEF DESCRIPTION OF THE DRAWINGS

FIG. 1 is a schematic view showing a polishing apparatus;

FIG. 2 is a horizontal cross-sectional view showing a heat exchanger;

FIG. 3 is a plan view showing a positional relationship between the heat exchanger and a polishing head on a polishing pad;

FIG. 4 is a cross-sectional view schematically showing an interior structure of the heat exchanger;

FIG. 5 is a cross-sectional view schematically showing an interior structure of a heat exchanger according to another embodiment;

FIG. 6 is a cross-sectional view schematically showing an interior structure of a heat exchanger according to another embodiment;

FIG. 7 is a cross-sectional view schematically showing an interior structure of a heat exchanger according to another embodiment;

FIG. 8 is a cross-sectional view schematically showing an interior structure of a heat exchanger according to another embodiment;

FIG. 9A, FIG. 9B, and FIG. 9C are diagrams for explaining a process of polishing a wafer with the polishing apparatus having the heat exchanger; and

FIG. 10 is a schematic diagram showing a configuration of an operation controller.

### DESCRIPTION OF EMBODIMENTS

Embodiments will now be described with reference to the drawings.

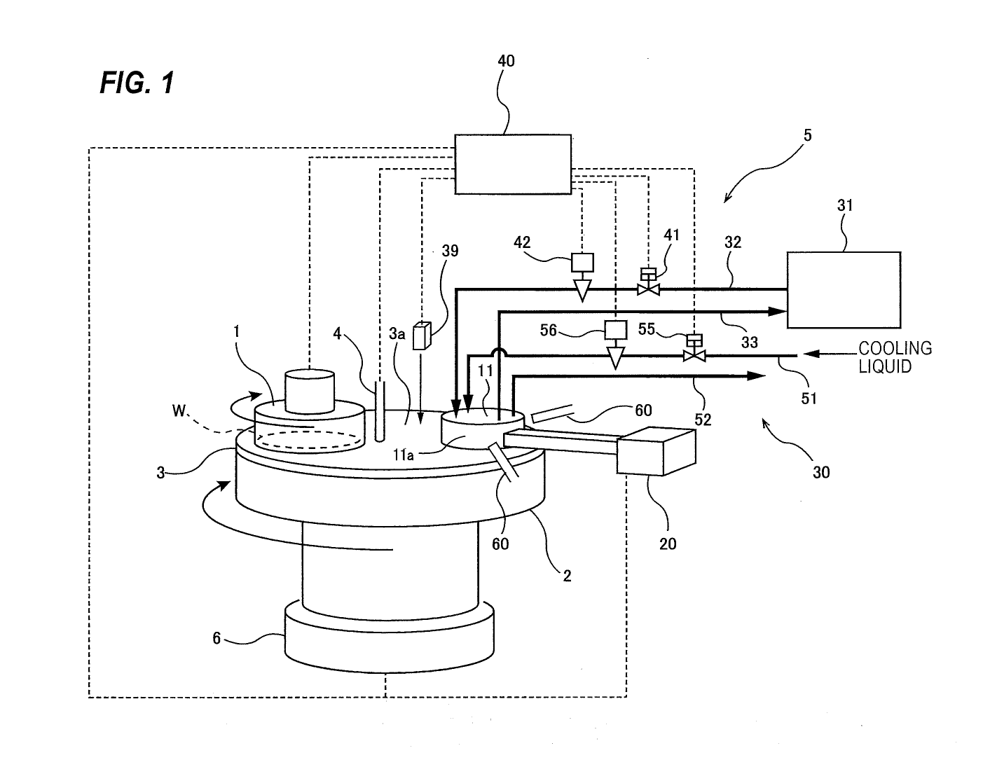

FIG. 1 is a schematic view of a polishing apparatus. As shown in FIG. 1, the polishing apparatus includes a polishing head 1 for holding and rotating a wafer W which is an example of a substrate, a polishing table 2 that supports a polishing pad 3, a liquid supply nozzle 4 for supplying a slurry or pure water selectively onto a surface of the polishing pad 3, and a pad-temperature regulating apparatus 5 for regulating a surface temperature of the polishing pad 3. The surface (upper surface) of the polishing pad 3 provides a polishing surface 3a for polishing the wafer W. The liquid supply nozzle 4 is constituted by a combination of a slurry nozzle for supplying slurry and a pure water nozzle for supplying pure water.

The polishing head 1 is vertically movable, and is rotatable about its axis in a direction indicated by arrow. The wafer W is held on a lower surface of the polishing head 1 by, for example, vacuum suction. A table motor 6 is coupled to the polishing table 2, so that the polishing table 2 can rotate in a direction indicated by arrow. As shown in FIG. 1, the polishing head 1 and the polishing table 2 rotate in the same direction. The polishing pad 3 is attached to the upper surface of the polishing table 2.

The polishing apparatus includes an operation controller 40 for controlling operations of the polishing head 1, the table motor 6, the liquid supply nozzle 4, and the pad-temperature regulating apparatus 5. Polishing of the wafer W is performed in the following manner. The wafer W, to be polished, is held by the polishing head 1, and is then rotated by the polishing head 1. The polishing pad 3 is rotated together with the polishing table 2 by the table motor 6. While the wafer W and the polishing pad 3 are rotating, the slurry is supplied from the liquid supply nozzle 4 onto the surface of the polishing pad 3, and the surface of the wafer W is then pressed by the polishing head 1 against the polishing surface 3a of the polishing pad 3. The surface of the wafer W is polished by the sliding contact with the polishing pad 3 in the presence of the slurry. The surface of the wafer W is planarized by the chemical action of the slurry and the mechanical action of abrasive grains contained in the slurry.

After the polishing of the wafer W, a water polishing process is performed in which pure water is supplied from the liquid supply nozzle 4 to the polishing surface 3a of the polishing pad 3 while the wafer W is brought into contact with the pure water on the polishing pad 3.

The pad-temperature regulating apparatus 5 includes a heat exchanger 11 for regulating (or adjusting) the temperature of the polishing surface 3a by exchanging heat with the polishing pad 3, a liquid supply system 30 for supplying a heating liquid and a cooling liquid, both of which have regulated temperatures, to the heat exchanger 11, and an elevating mechanism 20 coupled to the heat exchanger 11. The heat exchanger 11 is located above the polishing surface 3a of the polishing pad 3, and the bottom surface of the heat exchanger 11 faces the polishing surface 3a of the polishing pad 3. The elevating mechanism 20 is configured to elevate and lower the heat exchanger 11. More specifically, the elevating mechanism 20 is configured to move the bottom surface of the heat exchanger 11 in a direction closer to the polishing surface 3a of the polishing pad 3 and in a direction away from the polishing surface 3a of the polishing pad 3. The elevating mechanism 20 includes an actuator (not shown) such as an electric motor or an air cylinder. The operation of the elevating mechanism 20 is controlled by the operation controller 40.

The liquid supply system 30 includes a heating-liquid supply tank 31 as a heating-liquid supply source for holding the heating liquid having a regulated temperature therein, and a heating-liquid supply pipe 32 and a heating-liquid return pipe 33, each coupling the heating-liquid supply tank 31 to the heat exchanger 11. One ends of the heating-liquid supply pipe 32 and the heating-liquid return pipe 33 are coupled to the heating-liquid supply tank 31, and the other ends are coupled to the heat exchanger 11.

The heating liquid having a regulated temperature is supplied from the heating-liquid supply tank 31 to the heat exchanger 11 through the heating-liquid supply pipe 32, flows in the heat exchanger 11, and is returned from the heat exchanger 11 to the heating-liquid supply tank 31 through the heating-liquid return pipe 33. In this manner, the heating liquid circulates between the heating-liquid supply tank 31 and the heat exchanger 11. The heating-liquid supply tank 31 has a heater (not shown in the drawings), so that the heating liquid is heated by the heater to have a predetermined temperature.

A first on-off valve 41 and a first flow control valve 42 are attached to the heating-liquid supply pipe 32. The first flow control valve 42 is located between the heat exchanger 11 and the first on-off valve 41. The first on-off valve 41 is a valve not having a flow rate regulating function, whereas the first flow control valve 42 is a valve having a flow rate regulating function.

The liquid supply system 30 further includes a cooling-liquid supply pipe 51 and a cooling-liquid discharge pipe 52, both of which are coupled to the heat exchanger 11. The cooling-liquid supply pipe 51 is coupled to a cooling-liquid supply source (e.g. a cold water supply source) provided in a factory in which the polishing apparatus is installed. The cooling liquid is supplied to the heat exchanger 11 through the cooling-liquid supply pipe 51, flows in the heat exchanger 11, and is drained from the heat exchanger 11 through the cooling-liquid discharge pipe 52. In one embodiment, the cooling liquid that has flowed through the heat exchanger 11 may be returned to the cooling-liquid supply source through the cooling-liquid discharge pipe 52.

A second on-off valve 55 and a second flow control valve 56 are attached to the cooling-liquid supply pipe 51. The second flow control valve 56 is located between the heat exchanger 11 and the second on-off valve 55. The second on-off valve 55 is a valve not having a flow rate regulating function, whereas the second flow control valve 56 is a valve having a flow rate regulating function.

The first on-off valve 41, the first flow control valve 42, the second on-off valve 55, and the second flow control valve 56 are coupled to the operation controller 40, so that operations of the first on-off valve 41, the first flow control valve 42, the second on-off valve 55, and the second flow control valve 56 are controlled by the operation controller 40.

The pad-temperature regulating apparatus 5 further includes a pad-temperature measuring device 39 for measuring a temperature of the polishing surface 3a of the polishing pad 3 (which may hereinafter be referred to as pad surface temperature). The pad-temperature measuring device 39 is coupled to the operation controller 40. The operation controller 40 is configured to operate the first flow control valve 42 and the second flow control valve 56 based on the pad surface temperature measured by the pad-temperature measuring device 39. The first on-off valve 41 and the second on-off valve 55 are usually open. A radiation thermometer, which can measure the temperature of the polishing surface 3a of the polishing pad 3 in a non-contact manner, can be used as the pad-temperature measuring device 39.

The pad-temperature measuring device 39 measures the surface temperature of the polishing pad 3 in a non-contact manner, and sends a measured value of the surface temperature to the operation controller 40. Based on the pad surface temperature measured, the operation controller 40 operates the first flow control valve 42 and the second flow control valve 56 to control the flow rates of the heating liquid and the cooling liquid so that the pad surface temperature is maintained at a preset target temperature. The first flow control valve 42 and the second flow control valve 56 operate according to control signals from the operation controller 40 and regulate the flow rates of the heating liquid and the cooling liquid to be supplied to the heat exchanger 11. Heat exchange occurs between the polishing pad 3 and the heating liquid and cooling liquid, flowing in the heat exchanger 11, whereby the pad surface temperature changes.

Such feedback control can maintain the temperature of the polishing surface 3a of the polishing pad 3 (i.e., the pad surface temperature) at a predetermined target temperature. A PID controller may be used as the operation controller 40. The target temperature of the polishing pad 3 is determined depending on the type of the wafer W or on the polishing process, and the determined target temperature is inputted into the operation controller 40 in advance.

Hot water may be used as the heating liquid to be supplied to the heat exchanger 11. The hot water that has been heated to about 80° C. by the heater of the heating-liquid supply tank 31 may be used. If the surface temperature of the polishing pad 3 is to be raised more quickly, a silicone oil may be used as the heating liquid. In the case of using a silicone oil as the heating liquid, the silicone oil may be heated to a temperature of not less than 100° C. (e.g. about 120° C.). Cold water or a silicone oil may be used as the cooling liquid to be supplied to the heat exchanger 11. In the case of using a silicone oil as the cooling liquid, the polishing pad 3 can be cooled quickly by coupling a chiller as a cooling-liquid supply source to the cooling-liquid supply pipe 51, and by cooling the silicone oil to a temperature of not more than 0° C. Pure water can be used as the cold water. In order to cool pure water to produce the cold water, a chiller may be used as a cooling-liquid supply source. In this case, cold water that has flowed through the heat exchanger 11 may be returned to the chiller through the cooling-liquid discharge pipe 52.

The heating-liquid supply pipe 32 and the cooling-liquid supply pipe 51 are completely independent pipes. Thus, the heating liquid and the cooling liquid can be simultaneously supplied to the heat exchanger 11 without mixing with each other. The heating-liquid return pipe 33 and the cooling-liquid discharge pipe 52 are also completely independent pipes. Thus, the heating liquid is returned to the heating-liquid supply tank 31 without mixing with the cooling liquid, while the cooling liquid is either drained or returned to the cooling-liquid supply source without mixing with the heating liquid.

The pad-temperature regulating apparatus 5 further includes a plurality of cleaning nozzles 60 for spraying pure water onto a side surface 11a of the heat exchanger 11 to clean the heat exchanger 11. These cleaning nozzles 60 are directed toward the side surface 11a. In this embodiment, two cleaning nozzles 60 are provided, while three or more cleaning nozzles 60 may be provided. The cleaning nozzles 60 are provided to remove the slurry, used for polishing the wafer W, from the side surface 11a of the heat exchanger 11 with a jet of pure water.

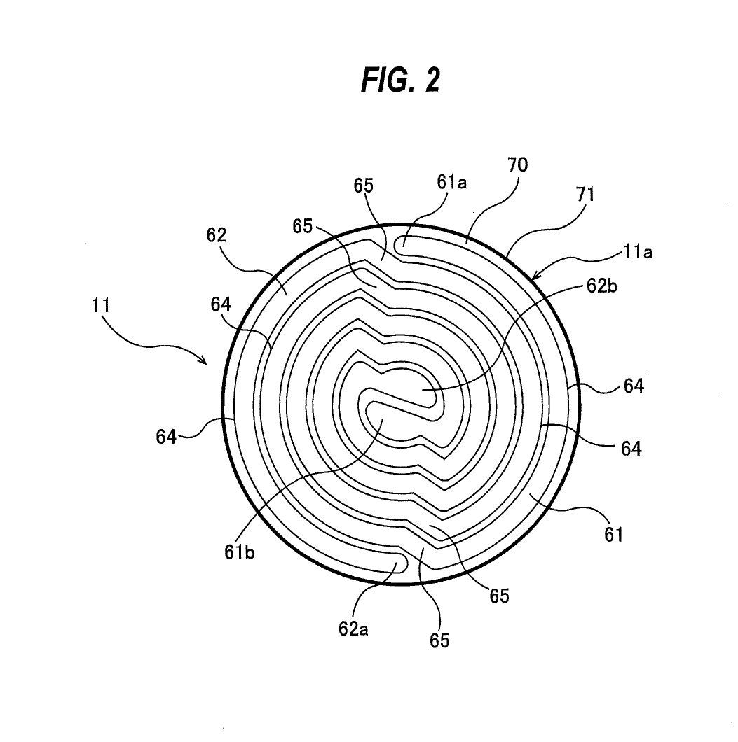

Next, the heat exchanger 11 will be described with reference to FIG. 2. FIG. 2 is a horizontal cross-sectional view showing the heat exchanger 11. As shown in FIG. 2, the heat exchanger 11 includes a flow passage structure 70 having a heating flow passage 61 and a cooling flow passage 62 formed therein, and a water-repellent material 71 that covers a side surface of the flow passage structure 70. The side surface 11a of the heat exchanger 11 is constituted by the water-repellent material 71. The flow passage structure 70 of this embodiment has a circular shape. In this embodiment, the entirety of the heat exchanger 11 has a circular shape, and the side surface 11a of the heat exchanger 11 has a cylindrical shape. The bottom surface of the heat exchanger 11 is flat and circular. The bottom surface of the heat exchanger 11 is constituted by a bottom surface of the flow passage structure 70. The flow passage structure 70 is made of a material having high wear resistance and high thermal conductivity. For example, the flow passage structure 70 is made of ceramic of dense SiC.

The heating flow passage 61 and the cooling flow passage 62 are adjacent to each other (or arranged side by side) and extend in a spiral shape. Further, the heating flow passage 61 and the cooling flow passage 62 have point symmetrical shapes and have the same length. Each of the heating flow passage 61 and the cooling flow passage 62 is basically composed of a plurality of arcuate flow passages 64 each having a constant curvature and a plurality of oblique flow passages 65 coupling these arcuate flow passages 64. Two adjacent arcuate flow passages 64 are coupled by each oblique flow passage 65.

According to such a configuration, outermost peripheral portions of the heating flow passage 61 and the cooling flow passage 62 can be located at the outermost periphery of the heat exchanger 11. Specifically, almost of the entire bottom surface of the heat exchanger 11 is located below the heating flow passage 61 and the cooling flow passage 62. Therefore, the heating liquid and the cooling liquid can quickly heat and cool the polishing surface 3a of the polishing pad 3. The heat exchange between the polishing pad 3 and the heating liquid and cooling liquid is performed in the presence of the slurry between the polishing surface 3a of the polishing pad 3 and the bottom surface of the heat exchanger 11.

The heating-liquid supply pipe 32 is coupled to an inlet 61a of the heating flow passage 61, while the heating-liquid return pipe 33 is coupled to an outlet 61b of the heating flow passage 61. The cooling-liquid supply pipe 51 is coupled to an inlet 62a of the cooling flow passage 62, while the cooling-liquid discharge pipe 52 is coupled to an outlet 62b of the cooling flow passage 62. The inlets 61a, 62a of the heating flow passage 61 and the cooling flow passage 62 are located at a peripheral portion of the heat exchanger 11, while the outlets 61b, 62b of the heating flow passage 61 and the cooling flow passage 62 are located at a central portion of the heat exchanger 11. Accordingly, the heating liquid and the cooling liquid flow spirally from the peripheral portion toward the central portion of the heat exchanger 11. The heating flow passage 61 and the cooling flow passage 62 are completely separated from each other, and therefore the heating liquid and the cooling liquid are not mixed with each other in the heat exchanger 11.

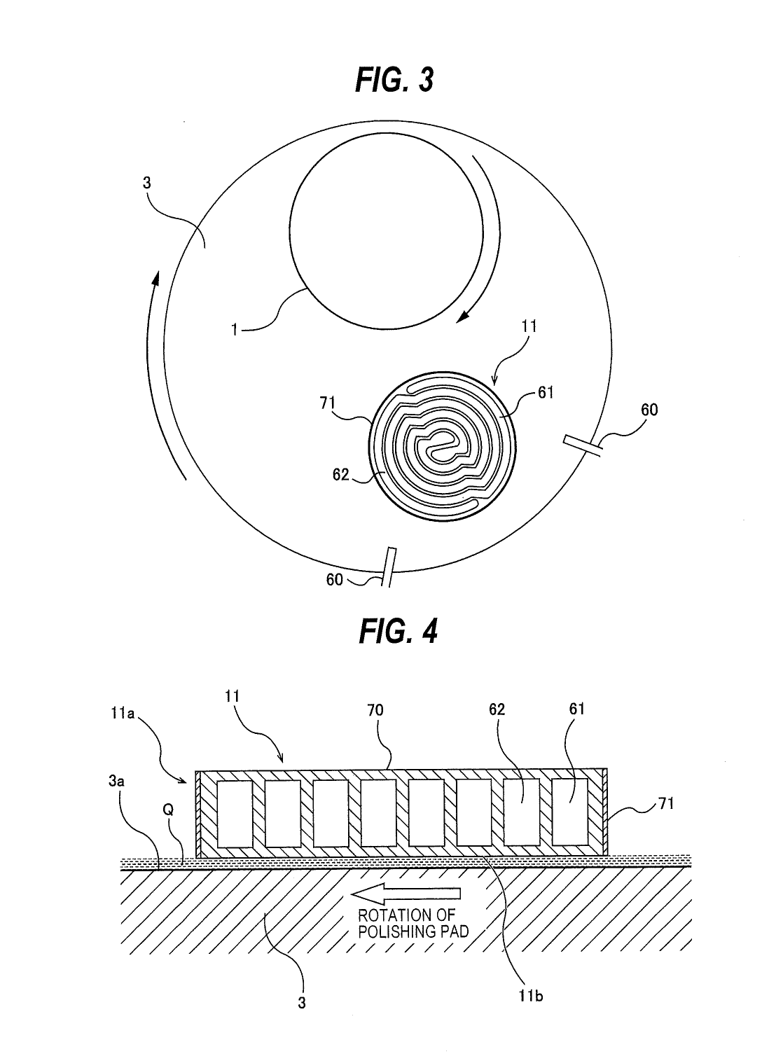

FIG. 3 is a plan view showing a positional relationship between the heat exchanger 11 and the polishing head 1 on the polishing pad 3. The heat exchanger 11 has a circular shape when viewed from above, and has a diameter which is smaller than the diameter of the polishing head 1. A distance from the center of rotation of the polishing pad 3 to the center of the heat exchanger 11 is equal to a distance from the center of rotation of the polishing pad 3 to the center of the polishing head 1. Since the heating flow passage 61 and the cooling flow passage 62 are adjacent to each other, the heating flow passage 61 and the cooling flow passage 62 are arranged not only along the radial direction of the polishing pad 3 but also along the circumferential direction of the polishing pad 3. Therefore, while the polishing table 2 and the polishing pad 3 are rotating, the polishing pad 3 in contact with the heat exchanger 11 performs the heat exchange with both of the heating liquid and the cooling liquid. The two cleaning nozzles 60 are arranged at both sides of the heat exchanger 11.

FIG. 4 is a cross-sectional view schematically showing an interior structure of the heat exchanger 11. The entirety of the side surface 11a of the heat exchanger 11 is constituted by the water-repellent material 71. The side surface 11a of the heat exchanger 11 of the present embodiment has a cylindrical shape, and the entire circumference of the side surface 11a of the heat exchanger 11 is constituted by the water-repellent material 71. In the present embodiment, the water-repellent material 71 is a coating layer made of polytetrafluoroethylene. Polytetrafluoroethylene is known as Teflon. Symbol Q in FIG. 4 represents the slurry. In one embodiment, in addition to the side surface 11a of the heat exchanger 11, the entirety of the bottom surface 11b of the heat exchanger 11 may be constituted by a water-repellent material. For example, the bottom surface 11b of the heat exchanger 11 may be constituted by a coating layer made of polytetrafluoroethylene.

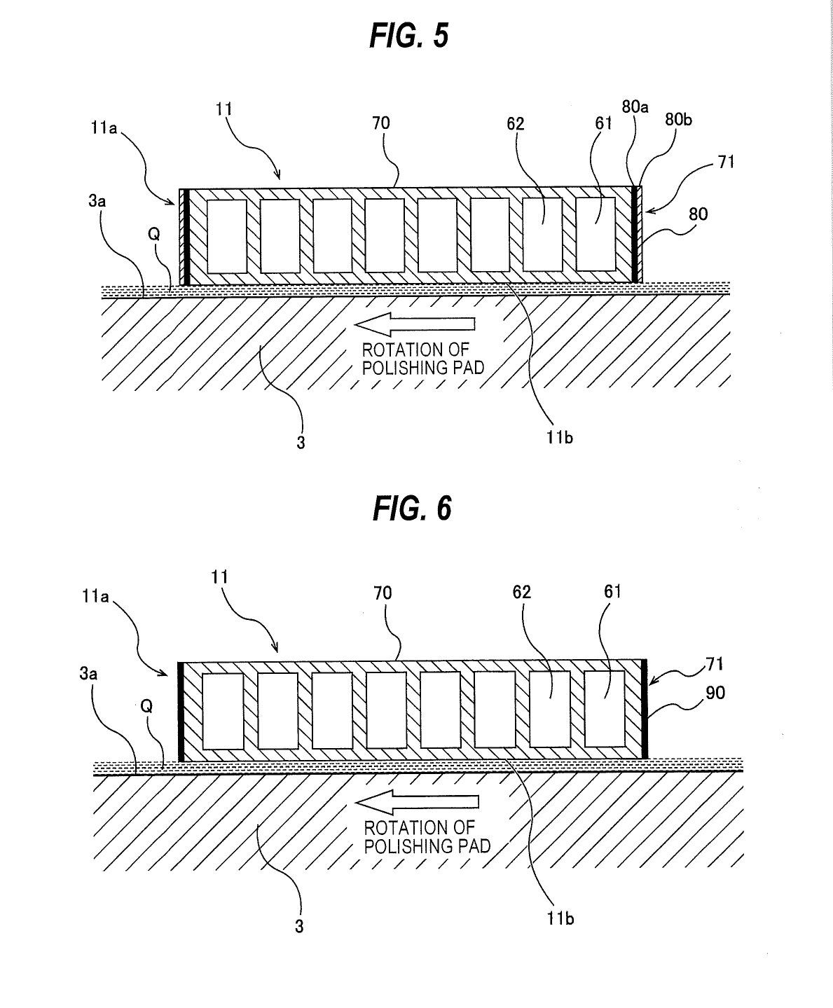

In one embodiment, as shown in FIG. 5, the water-repellent material 71 may be composed of a water-repellent adhesive tape 80. One surface of the water-repellent adhesive tape 80 is composed of an adhesive layer 80a, while the other surface is composed of a water-repellent layer 80b. The water-repellent layer 80b is made of a water-repellent material, such as polytetrafluoroethylene. The water-repellent adhesive tape 80 is attached to the side surface of the flow passage structure 70. When the water repellency of the adhesive tape 80 is lowered, the adhesive tape 80 is removed from the flow passage structure 70, and a new water-repellent adhesive tape 80 is attached to the side surface of the flow passage structure 70.

In one embodiment, as shown in FIG. 6, the water-repellent material 71 may be composed of a silicone rubber 90. Specifically, the side surface of the flow passage structure 70 is covered with the silicone rubber 90, and the entirety of the side surface 11a of the heat exchanger 11 is constituted by the silicone rubber 90. The silicone rubber 90 itself has the water repellency. Further, the silicone rubber 90 also functions as a heat insulating material. Therefore, even if the slurry adheres to the side surface 11a of the heat exchanger 11 constituted by the silicone rubber 90, the heat of the heating liquid flowing in the heat exchanger 11 is less likely to be transferred to the slurry on the silicone rubber 90. As a result, drying of the slurry attached to the silicone rubber 90 is prevented. Since the silicone rubber 90 functions as a heat insulating material, a thickness of the silicone rubber 90 is preferably 1 mm or more.

Furthermore, the silicone rubber 90 can reduce an impact on the wafer W in case the wafer W detached from the polishing head 1 collides with the side surface 11a of the heat exchanger 11 during the polishing of the wafer W. As a result, a damage to the wafer W when the wafer W is detached from the polishing head 1 can be minimized.

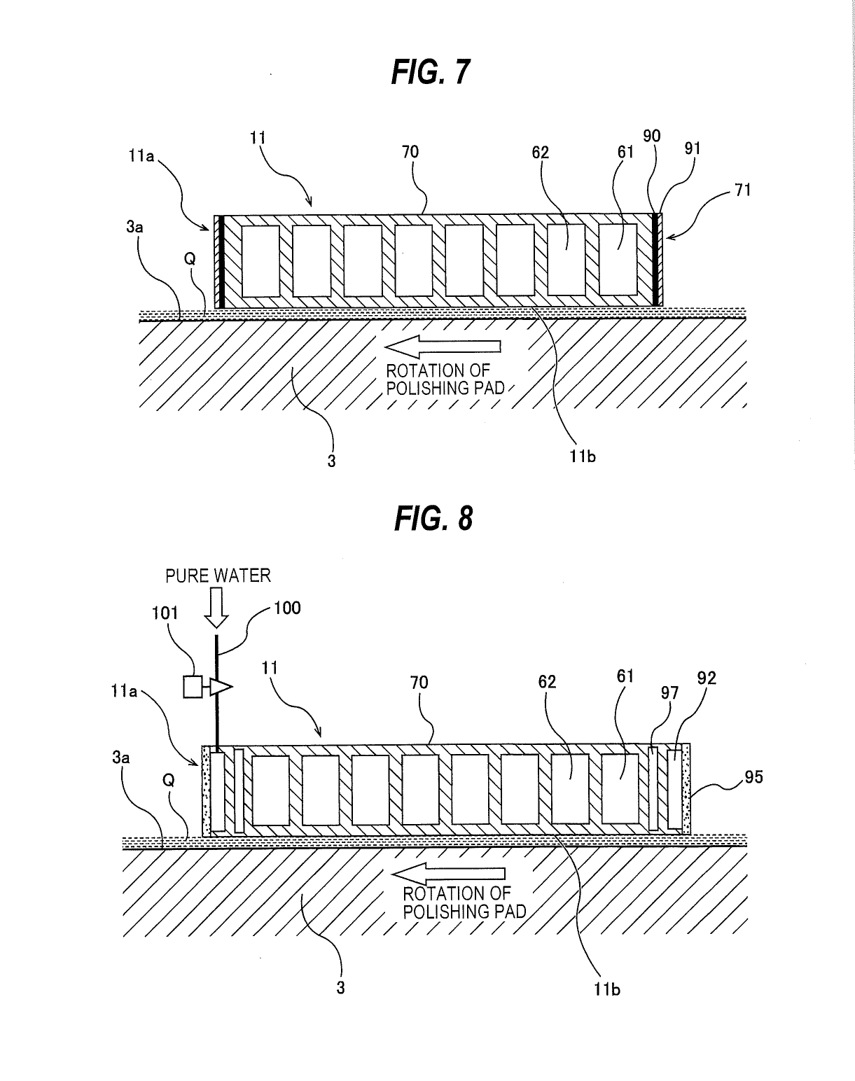

In one embodiment, as shown in FIG. 7, the water-repellent material 71 may comprise a silicone rubber 90 and a water-repellent coating layer 91. The silicone rubber 90 covers the side surface of the flow passage structure 70, and the water-repellent coating layer 91 covers an outer surface of the silicone rubber 90. The water-repellent coating layer 91 is made of, for example, polytetrafluoroethylene. Other configurations are the same as those of the embodiment shown in FIG. 6, and duplicate explanations will be omitted.

According to the embodiments shown in FIGS. 4 to 7, the slurry that has adhered to the surface of the water-repellent material 71 gathers during the polishing of the wafer W, and a volume of the slurry increases. As a result, the slurry is less likely to dry, and the slurry is prevented from firmly sticking to the side surface 11a of the heat exchanger 11 during polishing of the wafer W.

FIG. 8 is a cross-sectional view showing another embodiment of the heat exchanger 11. Configurations of the present embodiment, which are not specifically described, are the same as those of the embodiments described with reference to FIG. 1 to FIG. 7, and duplicate explanations will be omitted. As shown in FIG. 8, the heat exchanger 11 of this embodiment has a flow passage structure 70 and a porous material 95 fixed to a side portion of the flow passage structure 70. The flow passage structure 70 has the heating flow passage 61, the cooling flow passage 62, and a pure-water flow passage 92 formed therein. The porous material 95 is made of ceramic, such as silicon carbide, or aluminum oxide (alumina).

The pure-water flow passage 92 is located outwardly of the heating flow passage 61 and the cooling flow passage 62. The pure-water flow passage 92 surrounds the heating flow passage 61 and the cooling flow passage 62, and extends along an inner surface of the porous material 95. The flow passage structure 70 of the present embodiment is circular, as well as that in the embodiment shown in FIGS. 1 to 3. The pure-water flow passage 92 is an annular flow passage located at an outermost portion of the circular flow passage structure 70. The inner surface of the porous material 95 constitutes an outer wall of the pure-water flow passage 92, and the entirety of the side surface 11a of the heat exchanger 11 is constituted by the porous material 95.

A pure-water supply line 100 is coupled to the pure-water flow passage 92, and a pure-water flow control valve 101 is attached to the pure-water supply line 100. Pure water is supplied from a pure-water supply source (not shown) through the pure-water supply line 100 into the pure-water flow passage 92. A flow rate of the pure water supplied to the pure-water flow passage 92 is controlled by the pure-water flow control valve 101. The pure water fills the pure-water flow passage 92 and contacts the inner surface of the porous material 95. The pure water passes through the porous material 95 little by little, and exudes from the outer surface of the porous material 95.

According to the present embodiment, the side surface 11a of the heat exchanger 11 is composed of the porous material 95. The pure water flowing in the pure-water flow passage 92 passes through the porous material 95 and exudes from the outer surface of the porous material 95, i.e., from the side surface 11a of the heat exchanger 11. As a result, the side surface 11a of the heat exchanger 11 is maintained in a wet state. Therefore, the slurry that has adhered to the side surface 11a of the heat exchanger 11 is not dried, and the slurry is prevented from firmly sticking to the porous material 95.

The flow rate of the pure water that exudes from the porous material 95 can be regulated by the pure-water flow control valve 101. During polishing of the wafer W, the pure water is continuously supplied to the pure-water flow passage 92 in order to maintain the side surface 11a of the heat exchanger 11 wet. After the polishing of the wafer W, in order to maintain the side surface 11a of the heat exchanger 11 wet, the pure water continues to be supplied to the pure-water flow passage 92 while the side surface 11a of the heat exchanger 11 is being cleaned with pure water supplied from the cleaning nozzles 60 shown in FIG. 1. The flow rate of the pure water supplied to the pure-water flow passage 92 when the side surface 11a of the heat exchanger 11 is being cleaned by the cleaning nozzles 60 may be lower than the flow rate of the pure water supplied to the pure-water flow passage 92 during polishing of the wafer W.

As shown in FIG. 8, a heat insulating layer 97 is arranged between the heating flow passage 61 and the pure-water flow passage 92. The heat insulating layer 97 extends so as to surround the heating flow passage 61 and the cooling flow passage 62, and is located inwardly of the pure-water flow passage 92. The heat insulating layer 97 can be constituted by a heat insulating material or an air layer. The heat insulating layer 97 can prevent the heat of the heating liquid flowing in the heating flow passage 61 from being transmitted to the porous material 95, and can therefore prevent drying of the slurry on the side surface 11a of the heat exchanger 11 constituted by the outer surface of the porous material 95. Moreover, the heat insulating layer 97 can prevent the heat of the heating liquid flowing in the heating flow passage 61 from being removed away by the pure water in the pure-water flow passage 92, and can therefore prevent a decrease in the heat exchanging capability. The heat insulating layer 97 can be applied to the embodiments shown in FIGS. 4 to 7.

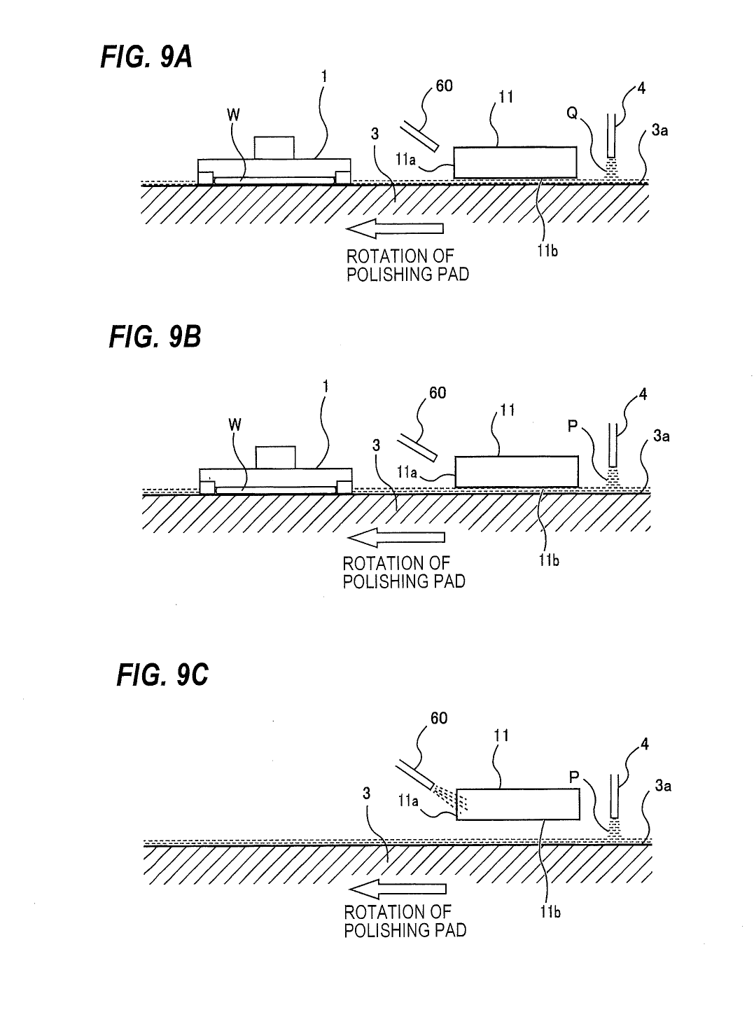

Next, a process of polishing a wafer with the polishing apparatus having the above-described heat exchanger 11 will be described with reference to FIGS. 1, 9A to 9C. The heat exchanger 11 shown in FIGS. 9A to 9C is the heat exchanger 11 shown in any one of FIGS. 4 to 8.

As shown in FIG. 1, the polishing table 2 is rotated by the table motor 6, and the polishing pad 3 on the polishing table 2 rotates. The polishing head 1 holding the wafer W on its lower surface is rotated by a motor (not shown). The heat exchanger 11 is moved toward the polishing surface 3a by the elevating mechanism 20 until the heat exchanger 11 comes into contact with the polishing surface 3a.

As shown in FIG. 9A, while the slurry Q is being supplied from the liquid supply nozzle 4 onto the polishing surface 3a of the polishing pad 3, the wafer W is pressed against the polishing surface 3a of the polishing pad 3 by the polishing head 1, so that the wafer W is polished. During polishing of the wafer W, the bottom surface 11b of the heat exchanger 11 faces the polishing surface 3a of the polishing pad 3. During polishing of the wafer W, the heat exchange is performed between the polishing pad 3 and the heating liquid and cooling liquid flowing in the heat exchanger 11. Specifically, with the slurry Q present between the polishing surface 3a of the polishing pad 3 and the bottom surface 11b of the heat exchanger 11, the heat exchange occurs between the polishing pad 3 and the heating liquid and cooling liquid flowing in the heat exchanger 11. As a result, the temperature of the polishing surface 3a of the polishing pad 3 during the polishing of the wafer W is maintained at a preset target temperature.

As shown in FIG. 9B, after the polishing of the wafer W, a water polishing process is carried out in which pure water P is supplied from the liquid supply nozzle 4 onto the polishing surface 3a of the polishing pad 3, while the wafer W is placed in contact with the pure water P on the polishing pad 3. In this water polishing process, the polishing head 1 applies a lower pressure to the wafer W than that when the wafer W is polished using the above-described slurry. The polished surface of the wafer W is cleaned with the pure water P, so that the slurry and polishing debris are removed from the wafer W. During the water polishing process, the bottom surface 11b of the heat exchanger 11 is in contact with the pure water P on the polishing surface 3a of the polishing pad 3, so that the slurry is washed off with the pure water P from the bottom surface 11b of the heat exchanger 11. During the water polishing process, a gap between the bottom surface 11b of the heat exchanger 11 and the polishing surface 3a of the polishing pad 3 is filled with flow of the pure water P.

As shown in FIG. 9C, after the water polishing process, the heat exchanger 11 is moved upward by the elevating mechanism 20 to separate the heat exchanger 11 from the polishing surface 3a of the polishing pad 3. The pure water is sprayed from the cleaning nozzles 60 to the side surface 11a of the heat exchanger 11 to wash away the slurry adhering to the side surface 11a of the heat exchanger 11. During the cleaning with the cleaning nozzles 60, dressing of the polishing surface 3a of the polishing pad 3 may be performed by a dresser (not shown).

As discussed above, according to the present embodiment, the bottom surface 11b of the heat exchanger 11 is cleaned with flow of the pure water on the polishing pad 3 during the water polishing process, and the side surface 11a of the heat exchanger 11 is cleaned by the cleaning nozzles 60. Thus, substantially all of the slurry can be removed from the heat exchanger 11 before the next wafer is polished.

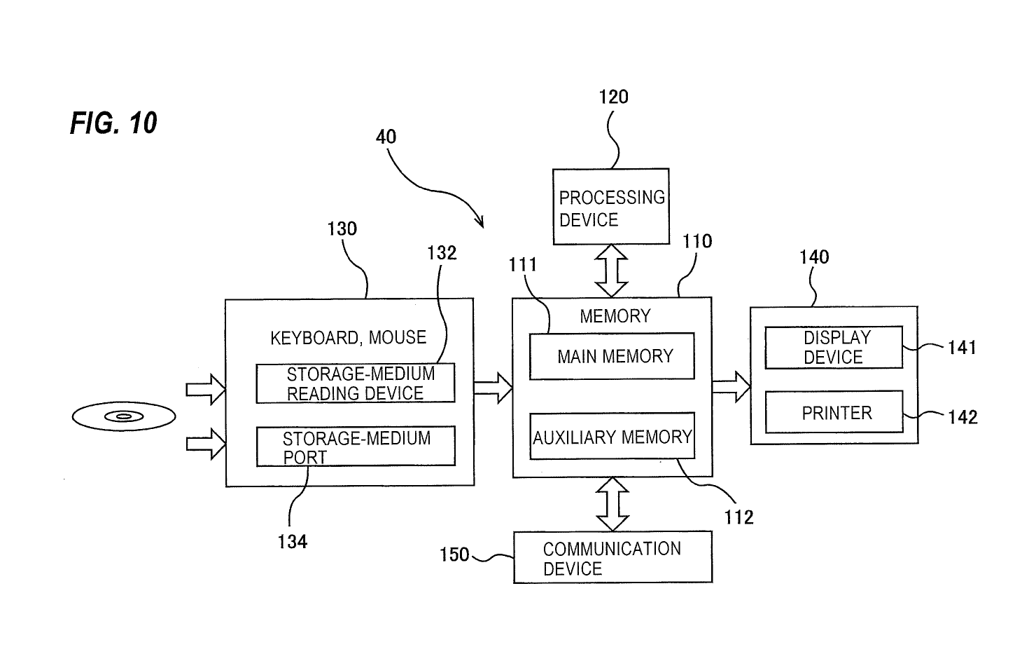

The operation of the above-described polishing apparatus is controlled by the operation controller 40. The operation controller 40 is constituted by a dedicated computer or a general-purpose computer. FIG. 10 is a schematic view showing an example of a structure of the operation controller 40. As shown in FIG. 10, the operation controller 40 includes a memory 110 in which a program and data are stored, a processing device 120, such as CPU (central processing unit), for performing arithmetic operation according to the program stored in the memory 110, an input device 130 for inputting the data, the program, and various information into the memory 110, an output device 140 for outputting processing results and processed data, and a communication device 150 for connecting to a network, such as the Internet.

The memory 110 includes a main memory 111 which is accessible by the processing device 120, and an auxiliary memory 112 that stores the data and the program therein. The main memory 111 may be a random-access memory (RAM), and the auxiliary memory 112 is a storage device which may be a hard disk drive (HDD) or a solid-state drive (SSD).

The input device 130 includes a keyboard and a mouse, and further includes a storage-medium reading device 132 for reading the data from a storage medium, and a storage-medium port 134 to which a storage medium can be coupled. The storage medium is a non-transitory tangible computer-readable storage medium. Examples of the storage medium include optical disk (e.g., CD-ROM, DVD-ROM) and semiconductor memory (e.g., USB flash drive, memory card). Examples of the storage-medium reading device 132 include optical drive (e.g., CD-ROM drive, DVD-ROM drive) and card reader. Examples of the storage-medium port 134 include USB port. The program and/or the data stored in the storage medium is introduced into the operation controller 40 via the input device 130, and is stored in the auxiliary memory 112 of the memory 110. The output device 140 includes a display device 141 and a printer 142.

The operation controller 40, which is constituted by a computer, operates according to the program electrically stored in the memory 110. Specifically, the operation controller 40 performs the steps of: instructing the table motor 6 to rotate the polishing table 2; instructing the polishing head 1 (or an elevating device and a motor of the polishing head 1 which are not shown) to rotate the polishing head 1 and cause the polishing head 1 to press the wafer W against the polishing surface 3a of the polishing pad 3 on the polishing table 2 while instructing the liquid supply nozzle 4 to supply the slurry from the slurry nozzle of the liquid supply nozzle 4 onto the polishing surface 3a; instructing the elevating mechanism 20 during polishing of the wafer W to move the heat exchanger 11 toward the polishing surface 3a to perform the heat exchange between the polishing pad 3 and the heating liquid and cooling liquid flowing in the heat exchanger 11 in the presence of the slurry between the polishing surface 3a of the polishing pad 3 and the bottom surface 11b of the heat exchanger 11; and instructing the liquid supply nozzle 4 after polishing of the wafer W to supply the pure water onto the polishing surface 3a of the polishing pad 3 from the pure water nozzle of the liquid supply nozzle 4 to thereby bring the wafer W into contact with the pure water on the polishing surface 3a and bring the bottom surface 11b of the heat exchanger 11 into contact with the pure water on the polishing surface 3a, thereby washing away the slurry from the bottom surface 11b of the heat exchanger 11 with the pure water (i.e., instructing the polishing apparatus to perform the above-discussed water polishing process).

Further, after the water polishing process, the operation controller 40 performs the step of instructing the polishing head 1 and the elevating mechanism 20 to elevate the polishing head 1 and the heat exchanger 11 from the polishing surface 3a of the polishing pad 3, while instructing the cleaning nozzles 60 to spray pure water onto the side surface 11a of the heat exchanger 11 to thereby wash away the slurry adhering to the side surface 11a of the heat exchanger 11.

The program for causing the operation controller 40 to perform the above steps is stored in a non-transitory tangible computer-readable storage medium. The operation controller 40 is provided with the program via the storage medium. The operation controller 40 may be provided with the program via communication network, such as the Internet.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A heat exchanger comprising:
a flow passage structure having a first flow passage and a second flow passage formed therein; and
a water-repellent material covering a side surface of the flow passage structure, a side surface of the heat exchanger being constituted by the water-repellent material.

2. The heat exchanger according to claim 1, wherein the water-repellent material comprises a coating layer made of polytetrafluoroethylene.

3. The heat exchanger according to claim 1, wherein the water-repellent material comprises a water-repellent adhesive tape.

4. The heat exchanger according to claim 1, wherein the water-repellent material comprises a silicone rubber.

5. The heat exchanger according to claim 1, wherein the water-repellent material comprises a silicone rubber and a water-repellent coating layer, the water-repellent coating layer covering an outer surface of the silicone rubber.

6. A heat exchanger comprising:
a flow passage structure having a first flow passage, a second flow passage, and a pure-water flow passage formed therein, the pure-water flow passage surrounding the first flow passage and the second flow passage; and
a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

7. The heat exchanger according to claim 6, further comprising a heat insulating layer located between the first flow passage and the pure-water flow passage.

8. The heat exchanger according to claim 7, wherein the heat insulating layer comprises an air layer.

9. The heat exchanger according to claim 6, wherein the porous material is made of ceramic.

10. A polishing apparatus comprising:
a polishing table for supporting a polishing pad;
a polishing head configured to press a substrate against a polishing surface of the polishing pad;
a liquid supply nozzle configured to supply slurry or pure water selectively onto the polishing surface of the polishing pad; and
a heat exchanger configured to regulate a temperature of the polishing surface by performing heat exchange with the polishing pad, the heat exchanger including:
a flow passage structure having a first flow passage and a second flow passage formed therein; and
a water-repellent material covering a side surface of the flow passage structure, a side surface of the heat exchanger being constituted by the water-repellent material.

11. A polishing apparatus comprising:
a polishing table for supporting a polishing pad;
a polishing head configured to press a substrate against a polishing surface of the polishing pad;
a liquid supply nozzle configured to supply slurry or pure water selectively onto the polishing surface of the polishing pad; and
a heat exchanger configured to regulate a temperature of the polishing surface by performing heat exchange with the polishing pad, the heat exchanger including:
a flow passage structure having a first flow passage, a second flow passage, and a pure-water flow passage formed therein, the pure-water flow passage surrounding the first flow passage and the second flow passage; and
a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

12. A polishing method comprising:
pressing a substrate against a polishing surface of a polishing pad while supplying slurry onto the polishing surface, thereby polishing the substrate;
during polishing of the substrate, performing heat exchange between the polishing pad and heating and cooling liquids flowing in a heat exchanger in the presence of the slurry between the polishing surface of the polishing pad and a bottom surface of the heat exchanger;
after polishing of the substrate, performing a water polishing process in which pure water is supplied onto the polishing surface of the polishing pad while the substrate is brought into contact with the pure water on the polishing pad; and
during the water polishing process, bringing the bottom surface of the heat exchanger into contact with the pure water on the polishing surface of the polishing pad, thereby washing away the slurry from the bottom surface of the heat exchanger,
wherein the heat exchanger includes:
a flow passage structure having a heating flow passage and a cooling flow passage formed therein; and
a water-repellent material covering a side surface of the flow passage structure, a side surface of the heat exchanger being constituted by the water-repellent material.

13. The polishing method according to claim 12, further comprising spraying pure water onto the side surface of the heat exchanger after the water polishing process.

14. A polishing method comprising:
pressing a substrate against a polishing surface of a polishing pad while supplying slurry onto the polishing surface, thereby polishing the substrate;
during polishing of the substrate, performing heat exchange between the polishing pad and heating and cooling liquids flowing in a heat exchanger in the presence of the slurry between the polishing surface of the polishing pad and a bottom surface of the heat exchanger;
after polishing of the substrate, performing a water polishing process in which pure water is supplied onto the polishing surface of the polishing pad while the substrate is brought into contact with the pure water on the polishing pad; and
during the water polishing process, bringing the bottom surface of the heat exchanger into contact with the pure water on the polishing surface of the polishing pad, thereby washing away the slurry from the bottom surface of the heat exchanger,
wherein the heat exchanger includes:
a flow passage structure having a heating flow passage, a cooling flow passage, and a pure-water flow passage formed therein, the pure-water flow passage surrounding the heating flow passage and the cooling flow passage; and
a porous material secured to a side portion of the flow passage structure, the pure-water flow passage extending along an inner surface of the porous material, the inner surface of the porous material constituting an outer wall of the pure-water flow passage, a side surface of the heat exchanger being constituted by an outer surface of the porous material.

15. The polishing method according to claim 14, further comprising spraying pure water onto the side surface of the heat exchanger after the water polishing process.

16. A non-transitory computer-readable storage medium storing a program for causing a computer to perform the steps of:
instructing a table motor to rotate a polishing table;
instructing a polishing head to press a substrate against a polishing surface of a polishing pad on the polishing table to polish the substrate, while instructing a liquid supply nozzle to supply slurry onto the polishing surface;
during polishing of the substrate, instructing an elevating mechanism to move a heat exchanger toward the polishing surface to perform heat exchange between the polishing pad and heating and cooling liquids flowing in the heat exchanger in the presence of the slurry between the polishing surface of the polishing pad and a bottom surface of the heat exchanger; and
after polishing of the substrate, instructing the liquid supply nozzle to supply pure water onto the polishing surface of the polishing pad to bring the substrate into contact with the pure water on the polishing surface and bring the bottom surface of the heat exchanger into contact with the pure water on the polishing surface to wash away the slurry from the bottom surface of the heat exchanger with the pure water.
